(19) United States
(12) Patent Application Publication
(10) Pub. No.: US 2026/0343844 A1
(43) Pub. Date: Oct. 29, 2026

(54) METHODS OF FORMING WEAK SRAM PFETS IN MCFETS AND THE STRUCTURES THEREOF

(71) Applicant: Taiwan Semiconductor Manufacturing Co., Ltd., Hsinchu (TW)

(72) Inventor: Zhi-Chang Lin, Zhubei City (TW)

(21) Appl. No.: 19/721,438

(22) Filed: Jun. 26, 2026

Related U.S. Application Data
(63) Continuation of application No. 18/982,296, filed on Dec. 16, 2024.
(60) Provisional application No. 63/699,906, filed on Sep. 27, 2024.

(51) Int. Cl. H10B 10/00

(52) U.S. Cl. CPC H10B 10/125

(57) ABSTRACT

A method includes forming a first source/drain recess in a first device region and between first neighboring multilayer stacks, and forming a second source/drain recess in a second device region and between second neighboring multilayer stacks. The first and the second source/drain recesses are formed in a common process. The method further includes forming a first dielectric liner in the second source/drain recess and on surfaces of the second neighboring multilayer stacks, selectively growing a first lower source/drain region in the first source/drain recess, removing the first dielectric liner, and forming a second dielectric liner in the first source/drain recess and on surfaces of the first neighboring multilayer stacks. A second lower source/drain region is grown in the second source/drain recess. The first lower source/drain region and the second lower source/drain region are of a same first conductivity type. The second dielectric liner is then removed.

### PRIORITY CLAIM AND CROSS-REFERENCE

This application is a continuation and claims the benefit of U.S. patent application Ser. No. 18/982,296 filed Dec. 16, 2024 and entitled “METHODS OF FORMING WEAK SRAM PFETS IN MCFETS AND THE STRUCTURES THEREOF,” which claims the benefit of the provisionally filed U.S. Patent application No. 63/699,906, filed on Sep. 27, 2024, and entitled “METHODS OF FORMING WEAK SRAM PFETS IN MCFETS AND THE STRUCTURES THEREOF,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIG. 2 through FIGS. 13A, 13B, 13C, and 13D are views of intermediate stages in the formation of CFETs in accordance with some embodiments.

FIG. 14 illustrates a schematic circuit diagram of a Static Random-Access Memory (SRAM) cell in accordance with some embodiments.

FIG. 15 illustrates a flow chart for forming CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

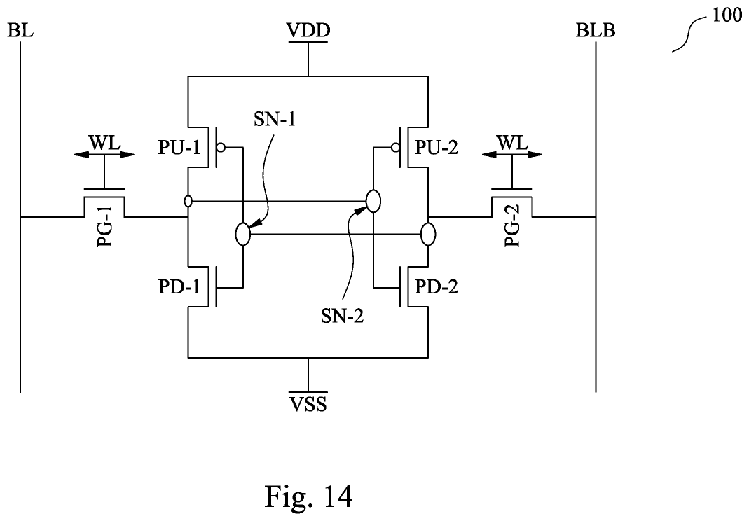

A first Complementary Field-Effect Transistor (CFET) and a second CFET and the method of forming the same are provided. In accordance with some embodiments, the first CFET is a part of a Static Random-Access Memory (SRAM) circuit/cell (such as what is shown in FIG. 14), and the second CFET is a part of a logic circuit. The SRAM circuit prefers weaker PFETs (with reduced drive currents) in order to have increased read-write margin. In subsequent discussion, the first CFET of the SRAM cell is referred to as an SRAM CFET, and the NFET and the PFET of the first CFET are referred to as an SRAM PFET and an SRAM NFET, respectively. The second CFET of the logic circuit is referred to as a logic CFET, and the NFET and the PFET of the logic circuit are referred to as a logic PFET and a logic NFET, respectively.

In accordance with some embodiments, the SRAM CFET and the logic CFET are formed sharing some common processes. The source/drain region of the SRAM NFET and the source/drain region of the logic NFET may be formed simultaneously. Source/drain region(s) may refer to a source or a drain, individually or collectively dependent upon the context. The source/drain region of the SRAM PFET and the source/drain region of the logic PFET are formed separately. To weaken the SRAM PFET, the source/drain region of the SRAM PFET may have lower germanium atomic percentage and/or lower boron concentration than the source/drain region of the logic PFET. The source/drain region of the logic PFET may also be formed closer to the channel region (through channel-push) than the source/drain region of the SRAM PFET.

It is appreciated that while in the example embodiments, PFETs are lower FETs in the CFETs, the PFETs may also be formed as the upper FETs in accordance with alternative embodiments. Certain circuits may prefer stronger or weaker NFETs, which can also be achieved through the concept of the embodiments of the present disclosure. Throughout the description, the terms “FET” and “transistor” are used interchangeably. Also, although a SRAM CFET and a logic CFET are used as examples, the embodiments may also be applied to other types of CFETs.

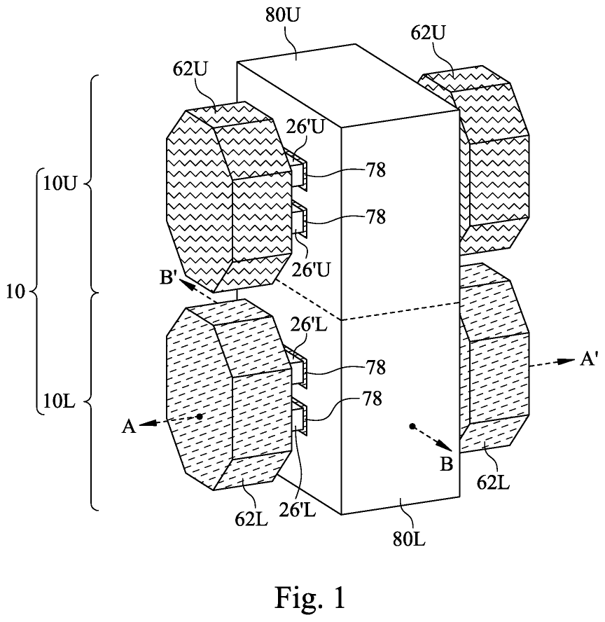

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Subsequent figures may refer to these reference cross-sections for clarity.

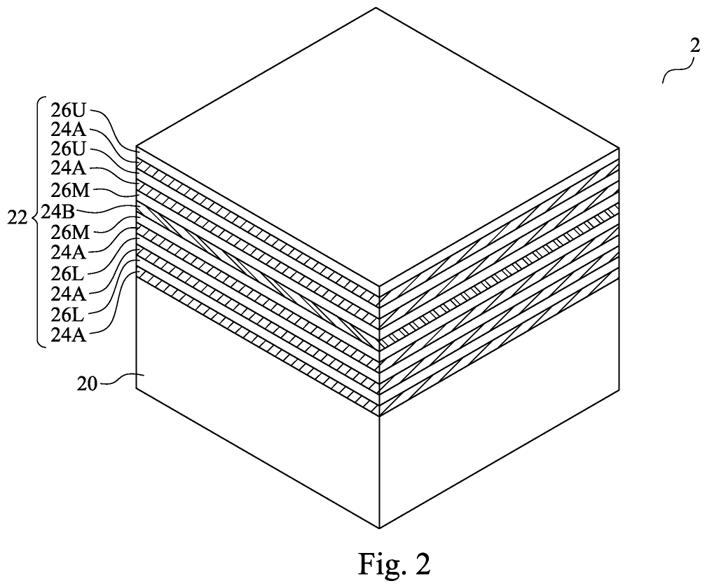

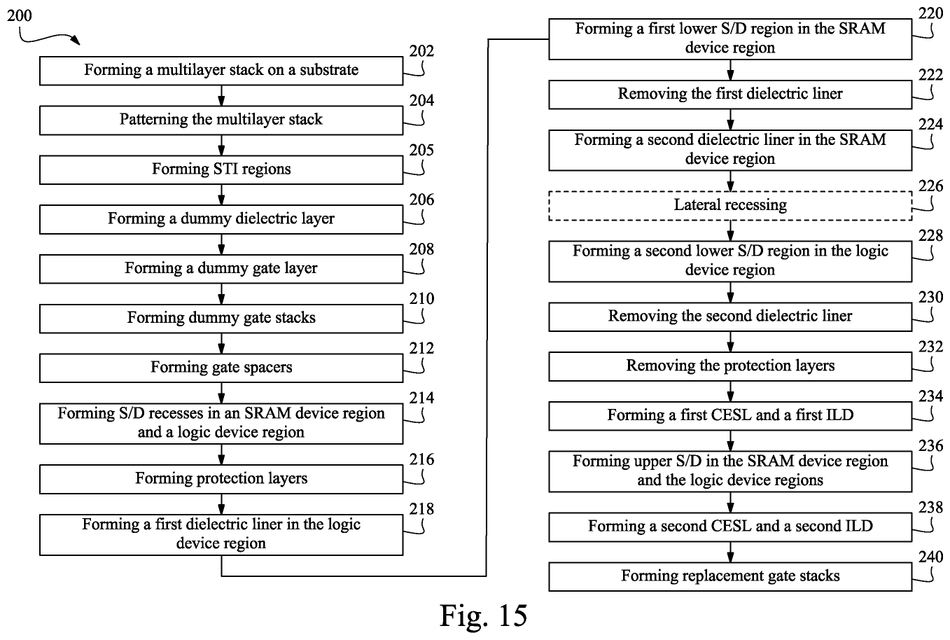

FIG. 2 through FIGS. 13A, 13B, 13C, and 13D illustrate the cross-sectional views of intermediate stages in the formation of CFETs (as schematically represented in FIG. 1) in accordance with some embodiments. The corresponding processes are referred to as monolithic CFET (mCFET) formation processes. The corresponding processes are also reflected schematically in the process flow shown in FIG. 15.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 20 may include silicon, germanium, carbon-doped silicon, a III-V compound semiconductor, or the like, or combinations thereof.

A multi-layer stack 22 is formed over the substrate 20. The respective process is illustrated as process 202 in the process flow 200 as shown in FIG. 15. The multi-layer stack 22 includes alternating dummy semiconductor layers 24 (including dummy semiconductor layers 24A and 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multi-layer stack 22 includes six of the dummy semiconductor layers 24 and six of the semiconductor layers 26. It should be appreciated that the multi-layer stack 22 may include any number of the dummy semiconductor layers 24 and the semiconductor layers 26. Each layer of the multi-layer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

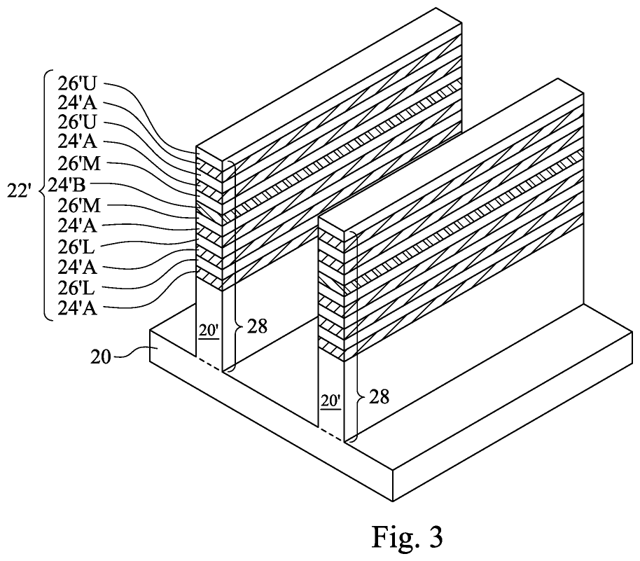

In FIG. 3, multi-layer stack 22 and substrate 20 are patterned to form semiconductor strips 28. The respective process is illustrated as process 204 in the process flow 200 as shown in FIG. 15. Each of semiconductor strips 28 includes semiconductor strip 20′ (the portions of the original substrate 20) and multi-layer stack 22', which is the remaining portion of multi-layer stack 22. The remaining portions 22′ of multi-layers stack 22 are referred to as nanostructures hereinafter, which are referred to using the corresponding reference number followed by a “′” sign. Accordingly, multi-layer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be individually and collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

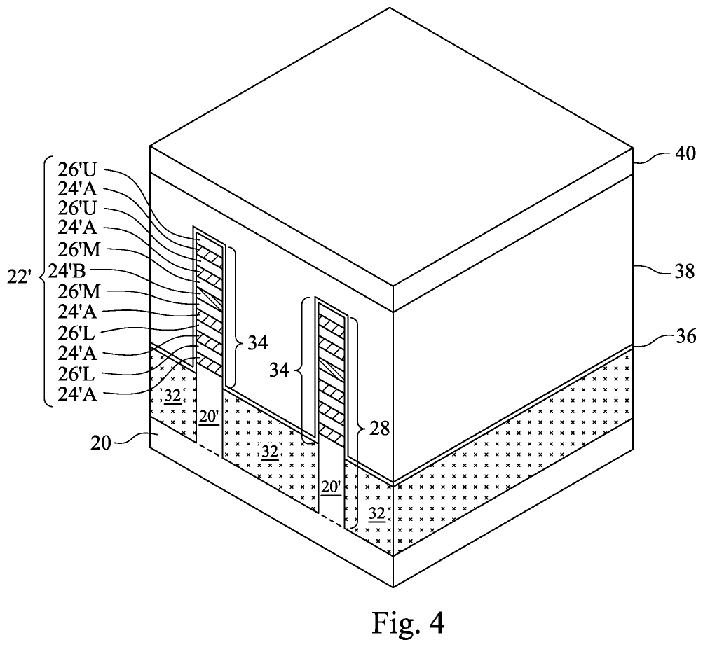

In FIG. 4, isolation regions 32 are formed over the substrate 20 and between adjacent semiconductor strips 28. The respective process is illustrated as process 205 in the process flow 200 as shown in FIG. 15. Isolation regions 32 may include a dielectric liner and a dielectric material over the dielectric liner. Isolation regions 32 are then recessed. Some upper portions of semiconductor strips 28 (including multi-layer stacks 22′) protrude higher than the remaining isolation regions 32 to form protruding fins 34.

Dummy dielectric layer 36 is then formed on the protruding fins 34. The respective process is illustrated as process 206 in the process flow 200 as shown in FIG. 15. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The respective process is illustrated as process 208 in the process flow 200 as shown in FIG. 15. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

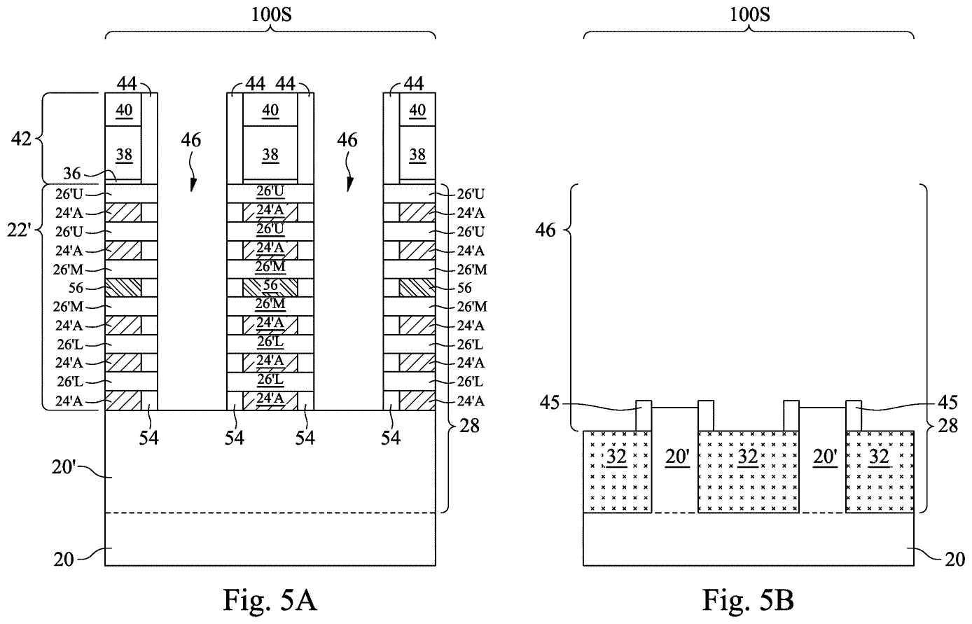

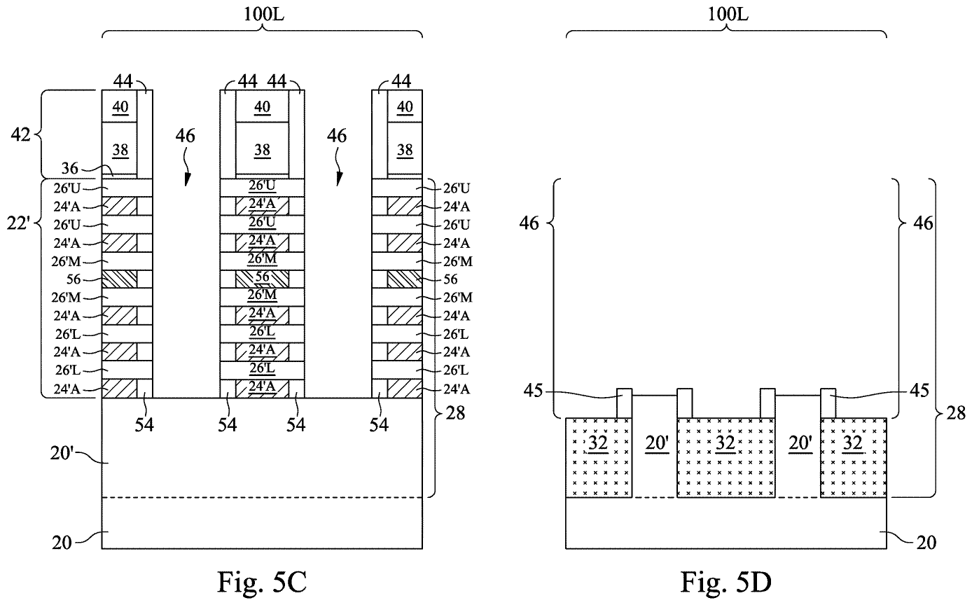

Next, the mask layer 40 may be patterned through photolithography and etching processes to form a mask, which is then used to etch and pattern dummy gate layer 38, and possibly dummy dielectric layer 36. A resulting structure is shown in FIGS. 5A and 5C. The remaining portions of mask layer 40, dummy gate layer 38, and dummy dielectric layer 36 form dummy gate stacks 42. The respective process is illustrated as process 210 in the process flow 200 as shown in FIG. 15.

In subsequent discussion, unless specified otherwise, the figures having digits followed by letter “A” or “C” illustrate the vertical cross-sectional views along a similar cross-section as vertical reference cross-section A-A′ in FIG. 1. The figures having digits followed by letter “B” or “D” illustrate the cross-sectional views along a similar cross-section as the vertical reference cross-section B-B′ in FIG. 1.

FIGS. 5A and 5B illustrate SRAM device region 100S, in which the CFETs of SRAM cells are to be formed. FIGS. 5C and 5D illustrate logic device region 100L, in which the CFETs of logic circuits are to be formed. FIGS. 5A and 5C illustrate the cross-sectional views along the channel length direction. FIGS. 5B and 5D illustrate the cross-sectional views parallel to the lengthwise direction of gate stacks, which cross-section cuts through the regions in which source/drain regions are to be formed. The structures shown in FIGS. 5A, 5B, 5C, and 5D may be formed in common processes as shown in FIGS. 2 through 4.

In FIGS. 5A and 5C, gate spacers 44 are formed over the multi-layer stacks 22′ and on exposed sidewalls of dummy gate stacks 42. The respective process is illustrated as process 212 in the process flow 200 as shown in FIG. 15. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. In FIGS. 5B and 5D, fin spacers 45 are illustrated, which are formed from the same dielectric layer(s) for forming gate spacers 44.

Source/drain recesses 46 are also formed in semiconductor strips 28 in both of SRAM device region 100S and logic device region 100L. The respective process is illustrated as process 214 in the process flow 200 as shown in FIG. 15. The source/drain recesses 46 are formed through etching semiconductor strips 28, and may extend through the multi-layer stacks 22′ and into the semiconductor strips 20′. The bottom surfaces of the source/drain recesses 46 may be at a level above, below, or level with the top surfaces of the isolation regions 32 (FIG. 4). In the etching processes, the gate spacers 44 and the dummy gate stacks 42 mask some portions of the semiconductor strips 28. The source/drain recesses 46 may be formed in SRAM device region 100S and logic device region 100L simultaneously in common processes.

Dummy nanostructures 24′A are then laterally recessed, and a dielectric material is filled into the respective recesses to form inner spacers 54, which are dielectric spacers. Dielectric isolation layers 56 are also formed to replace the dummy nanostructures 24′B.

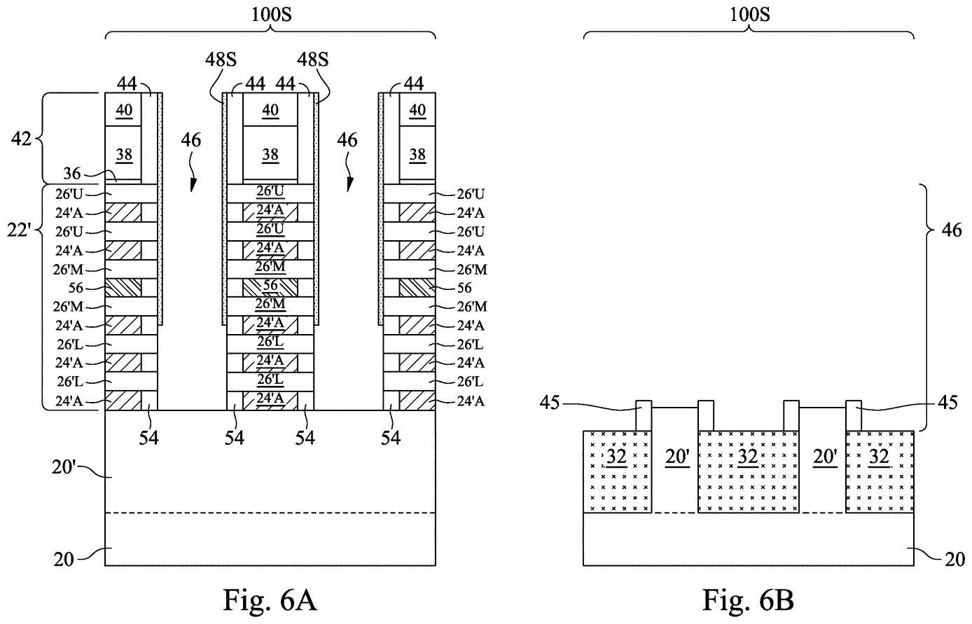

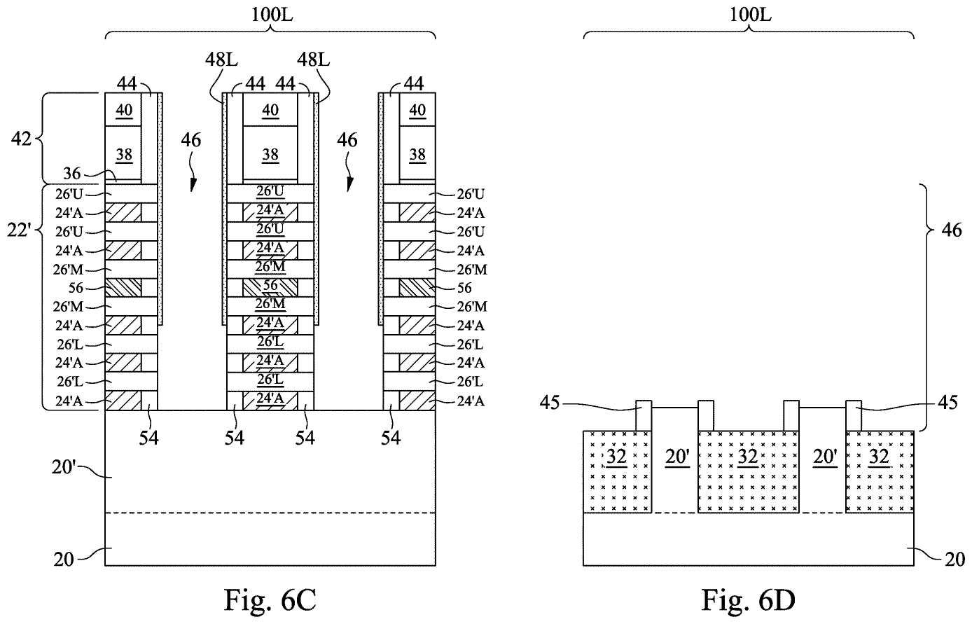

Referring to FIGS. 6A, 6B, 6C, and 6D, which illustrate the SRAM device region 100S and logic device region 100L, respectively, protection layers 48S and 48L are formed. Protection layers 48S and 48L may be formed in common processes or separate processes. The respective process is illustrated as process 216 in the process flow 200 as shown in FIG. 15. Protection layers 48S and 48L may be formed of or comprise silicon oxide, silicon nitride, silicon oxynitride, silicon oxy-carbo-nitride, silicon carbide, or the like, or combinations thereof. The material of protection layers 48S and 48L are further different from the materials of the exposed features such as gate spacers 44, hard masks 40, inner spacers 54, and the like, so that in the subsequent removal of protection layers 48S and 48L, the exposed features are not damaged.

In accordance with some embodiments, the formation of protection layers 48S and 48L may include depositing a sacrificial layer (not shown) filling the source/drain recesses 46, planarizing the sacrificial layer, and etching back the sacrificial layer. The top surface of the remaining sacrificial layer will be at the same level as the bottom end of the illustrated protection layers 48S and 48L. The sacrificial layer may comprise a photoresist or another polymer, which may be, or may not be photo sensitive.

A blanket protection layer is then deposited conformally, followed by an anisotropic etching process to remove the horizontal portions of the blanket protection layer, leaving the protection layers 48S and 48L as illustrated. The remaining portions of the sacrificial layer are then removed. In accordance with some embodiments, the bottom ends of the protection layers 48S and 48L are lower than the middle semiconductor nanostructures 26′M, and higher than the bottom surface of the lower semiconductor nanostructures 26′L that is immediately underlying the middle semiconductor nanostructures 26′M.

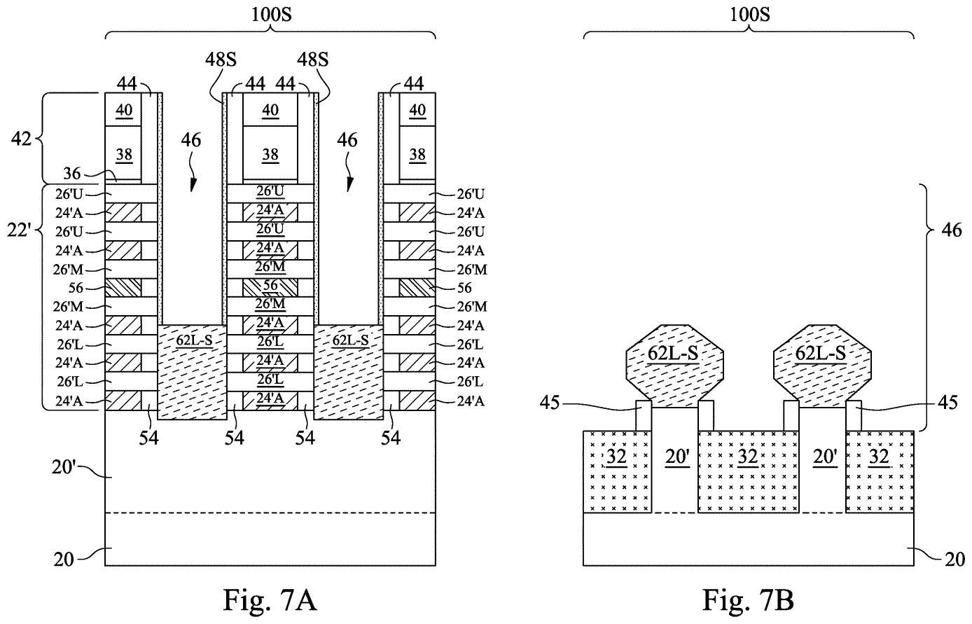

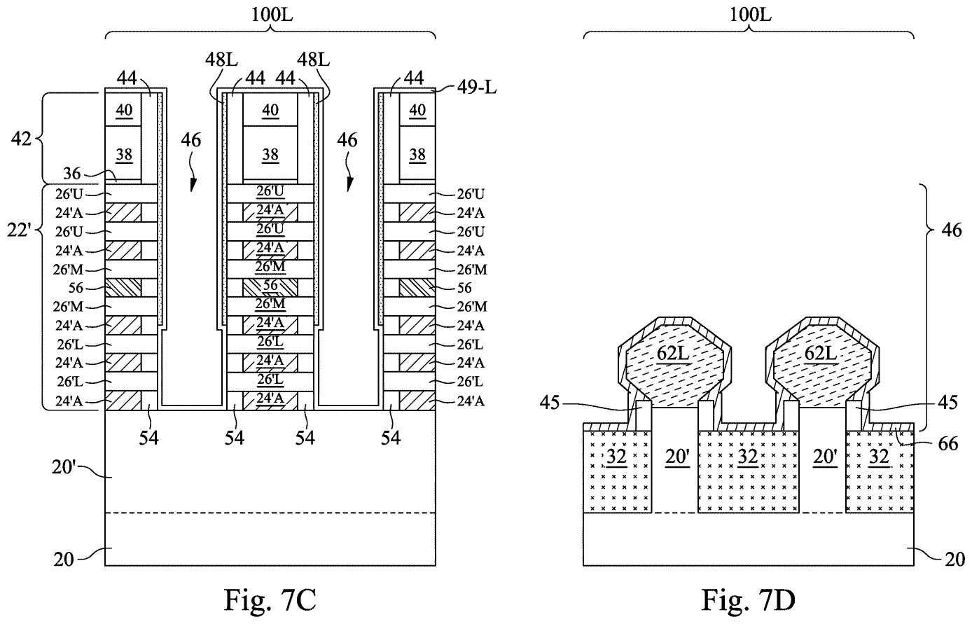

In a subsequent process, as shown in FIGS. 7C and 7D, a first dielectric liner 49L is formed in logic device region 100L. The respective process is illustrated as process 218 in the process flow 200 as shown in FIG. 15. The formation process may include depositing a conformal dielectric layer into both of SRAM device region 100S and logic device region 100L, and performing a patterning process through etching to remove the conformal dielectric layer from SRAM device region 100S. The deposition process may include a conformal deposition process such as ALD, CVD, or the like.

In accordance with some embodiments, the first dielectric liner 49L is formed of a material that is different from the material of protection layers 48S and 48L. The material of the first dielectric liner 49L may be (or may not be) selected from the same group of candidate materials for forming protection layer layers 48S and 48L. For example, the material of the first dielectric liner 49L may comprise silicon oxide, silicon nitride, silicon oxynitride, silicon oxy-carbo-nitride, silicon carbide, or the like, or combinations thereof.

After the formation of the first dielectric liner 49L, as shown in FIGS. 7A and 7B, lower source/drain regions 62L-S are formed in the lower portions of the source/drain recesses 46 in SRAM device region 100S. The respective process is illustrated as process 220 in the process flow 200 as shown in FIG. 15. The lower source/drain regions 62L-S are in contact with the lower semiconductor nanostructures 26′L and are not in contact with the upper semiconductor nanostructures 26′U. Inner spacers 54 physically and electrically insulate the lower source/drain regions 62L-S from the dummy nanostructures 24′A, which will be replaced with replacement gates in subsequent processes.

During the formation of lower source/drain regions 62L-S, which is performed through a selective epitaxy, due to the masking of dielectric liner 49L, the semiconductor material is not grown in the source/drain recesses 46 in logic device region 100L.

The lower source/drain regions 62L-S have a conductivity type that is suitable for the device type (p-type or n-type) of the lower nanostructure-FETs. In the following discussion, it is assumed that the lower nanostructure-FETs are PFETs, and the upper nanostructure-FETs are NFETs. In accordance with alternative embodiments, the lower nanostructure-FETs may be NFETs, and the upper nanostructure-FETs may be PFETs.

When lower source/drain regions 62L-S are p-type source/drain regions, the respective material may include silicon or silicon germanium, which is doped with a p-type dopant such as boron, indium, and/or the like. The lower source/drain regions 62L-S may be in-situ doped, and may be, or may not be, implanted with the corresponding p-type or n-type dopants.

In accordance with some embodiments, in order to weaken the PFET in SRAM device region 100S, the germanium atomic percentage of lower source/drain regions 62L-S is reduced. In accordance with some embodiments, the lower source/drain regions 62L-S comprise silicon without germanium. In accordance with alternative embodiments, the lower source/drain regions 62L-S comprise germanium with a relatively low germanium atomic percentage, for example, lower than about 30 percent.

The weakening of the PFET in SRAM device region 100S may also be achieved by reducing the p-type dopant (such as boron) concentration in lower source/drain regions 62L-S. In accordance with some embodiments, the p-type dopant (such as boron) concentration in lower source/drain regions 62L-S may be lower than about 5E20/cm³, and may be in the range between about 1E20/cm³ and³ about 5E20/cm³.

The weakening (or at least not enhancing) of the PFET in SRAM device region 100S may also be achieved by not performing a channel-push process. The channel-push process is the process to laterally recess lower semiconductor nanostructures 26′L, so that the resulting source/drain regions 62L-L is pushed closer to the respective channel. Accordingly, without performing the channel-push process, the lower source/drain regions 62L-L (such as silicon germanium boron) may have edges vertically aligned to the outer edges of inner spacers 54. The weakening of the PFET in SRAM device region 100S may adopt one, two, or three of the reducing germanium atomic percentage, reducing boron concentration, and not performing channel-push process in any combination.

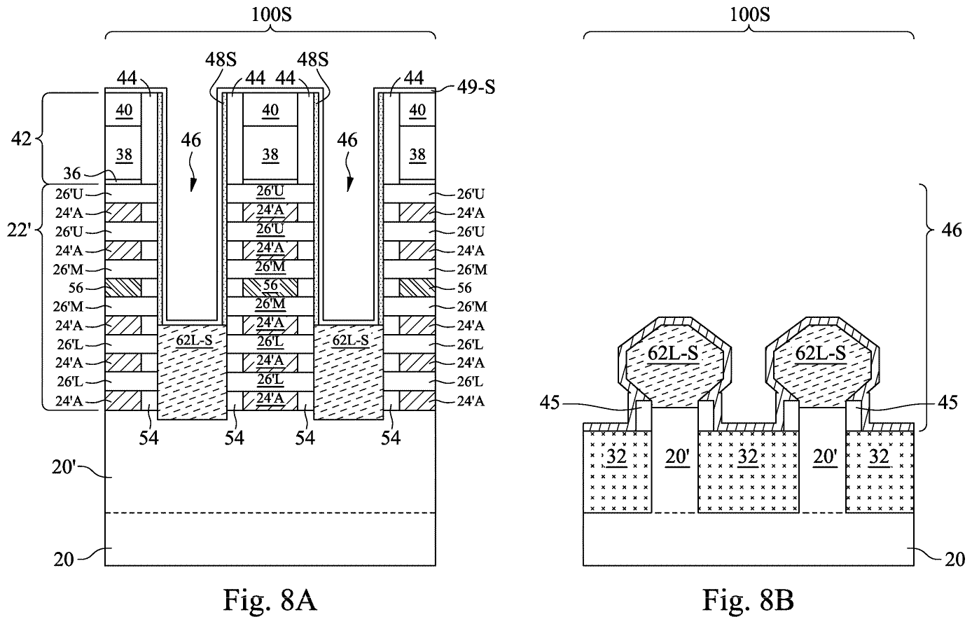

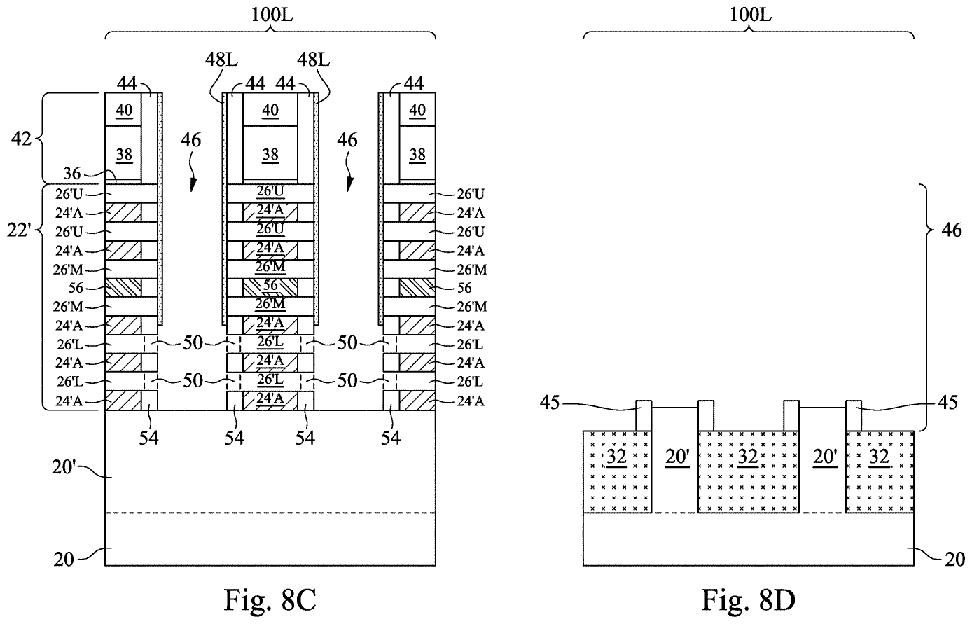

In a subsequent process, the protection liner 49L is removed, and the resulting structure in logic device region 100L is shown in FIGS. 8C and 8D. The respective process is illustrated as process 222 in the process flow 200 as shown in FIG. 15. The removal of the protection liner 49L may be performed through an isotropic etching process using a wet etching solution or an etching gas that attacks protection liner 49L, but not protection liners 48S and 48L, lower source/drain regions 62L-S, inner spacers 54, and semiconductor strip 20′. The sidewalls of lower semiconductor nanostructures 26′L in logic device region 100L are thus exposed.

In accordance with some embodiments, after the removal of protection liner 49L, a second dielectric liner 49S is formed in SRAM device region 100S, as shown in FIGS. 8A and 8B. The respective process is illustrated as process 224 in the process flow 200 as shown in FIG. 15. The material of the protection liner 49S may be selected from the same group of candidate materials for forming protection liner 49L, and may be the same as or different from the material of protection liner 49L.

The formation of the second dielectric liner 49S may also include depositing a conformal dielectric layer into both of SRAM device region 100S and logic device region 100L, and performing a patterning process through etching to remove the conformal dielectric layer from logic device region 100L. The deposition process may include a conformal deposition process such as ALD, CVD, or the like.

In accordance with some embodiments, as shown in FIG. 8C, after the formation of protection liner 49S to protect the components in SRAM device region 100S, a lateral recessing process (which is also referred to as a channel-push process) is performed to laterally recessing lower semiconductor nanostructures 26′L in logic device region 100L. Lateral recesses 50 are thus formed between the overlying and underlying inner spacers 54. The respective process is illustrated as process 226 in the process flow 200 as shown in FIG. 15. The sidewalls of the recessed lower semiconductor nanostructures 26′L may be directly underlying (and overlapped by) the overlying inner spacers 54, and directly overlying (and overlapping) the respective underlying inner spacers 54.

The formation of the lateral recesses 50 may advantageously cause the resulting epitaxy source/drain regions to be closer to the resulting channels, so that the resistance of the source/drain regions is reduced, and the drive current of the resulting logic PFET may be increased.

In accordance with alternative embodiments, the lateral recessing process is not performed. Accordingly, the lateral recesses 50 (FIG. 8C) are illustrated as being dashed to indicate that lateral recesses 50 may be, or may not be formed in accordance with some embodiments.

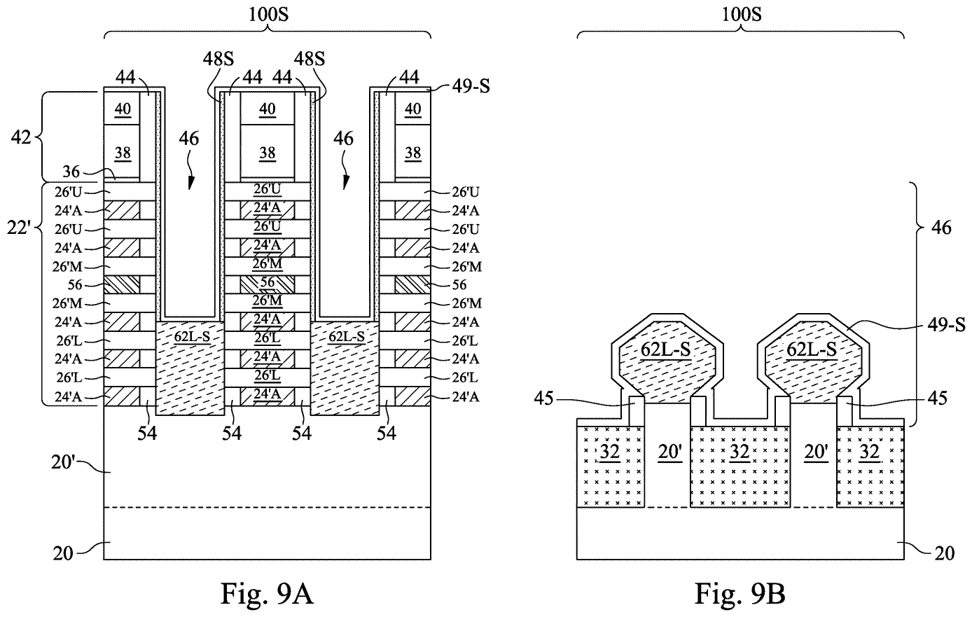

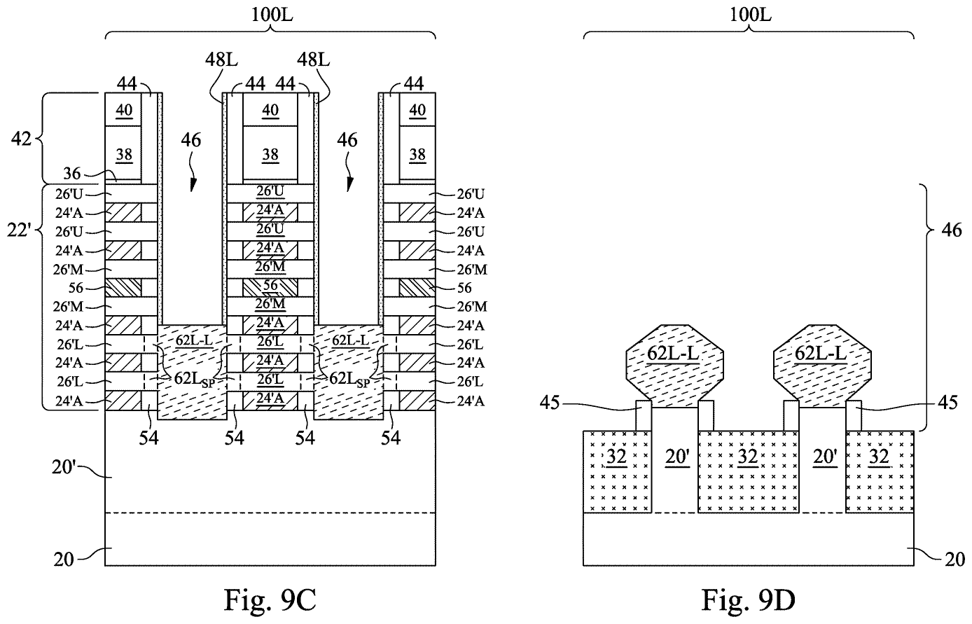

Referring to FIGS. 9C and 9D, lower source/drain regions 62L-L are formed in the lower portions of the source/drain recesses 46 (FIG. 8C) in logic device region 100L. The respective process is illustrated as process 228 in the process flow 200 as shown in FIG. 15. The lower source/drain regions 62L-L are in contact with the lower semiconductor nanostructures 26′L and are not in contact with the upper semiconductor nanostructures 26′U. Inner spacers 54 physically and electrically insulate the lower source/drain regions 62L-L from the dummy nanostructures 24′A, which will be replaced with replacement gates in subsequent processes.

During the formation of lower source/drain regions 62L-L, which is performed through a selective epitaxy process, due to the masking of dielectric liner 49S, the semiconductor material is not grown in the source/drain recesses 46 in SRAM device region 100S.

The lower source/drain regions 62L-L have a conductivity type that is suitable for the device type (which is p-type in the illustrative examples) of the lower nanostructure-FETs. When lower source/drain regions 62L-L are p-type source/drain regions, the respective material may include silicon or silicon germanium, which is doped with a p-type dopant such as boron, indium, and/or the like. The lower source/drain regions 62L-L may be in-situ doped, and may be, or may not be, implanted with the corresponding p-type or n-type dopants.

In accordance with some embodiments, the PFET in SRAM device region 100S is not weakened, and may be strengthened. Accordingly, the germanium atomic percentage of lower source/drain regions 62L-L may be increased to increase channel stress and thus the drive current. In accordance with some embodiments, the lower source/drain regions 62L-L comprise germanium with a relatively high germanium atomic percentage, for example, higher than about 50 percent, and may be in the range between about 50 percent and about 60 percent.

The strengthening of the PFET in SRAM device region 100S may also be achieved by increasing the p-type dopant (such as boron) concentration in lower source/drain regions 62L-L. In accordance with some embodiments, the p-type dopant (such as boron) concentration in lower source/drain regions 62L-L may be higher than about 5E20 cm³, and in the range between about 5E20/cm³ and³ about 2E21 cm³.

In accordance with some embodiments, the lower source/drain regions 62L-L (such as silicon germanium boron) may have portions 62L_{SP} in lateral recesses 50 (FIG. 9C) when the lateral recesses 50 are formed. The portions 62L_{SP} of the lower source/drain regions 62L-L in the lateral recesses 50 may comprise SiB, SiGeB, or the like. The germanium atomic percent and/or boron concentration in the portions 62L_{SP} may be lower than or equal to the germanium atomic percent and/or boron concentration in the portions of lower source/drain regions 62L-L outside of the lateral recesses 50. Furthermore, the germanium atomic percent and boron concentration in the portions 62L_{SP} are higher than in the channel regions (the remaining semiconductor nanostructures 22B).

In accordance with alternative embodiments in which the lateral recessing is not performed, the lower source/drain regions 62L-L may have edges vertically aligned to the outer edges of inner spacers 54. The PFET in logic device region 100L may adopt one, two, or all three methods for increasing currents, including increased germanium atomic percentage, increased boron concentration, and the channel-push process in any combination.

Due to the weakening of the PFET in SRAM device region 100S and/or the strengthening of the PFET in logic device region 100L, the drive current I_{P-L} of the PFET in logic device region 100L is higher than the drive current I_{P-S} of the PFET in SRAM device region 100S. It is appreciated that the terms “weakening” and “strengthening” are relative concepts. In accordance with some embodiments, ratio I_{P-L}/I_{P-S} is greater than about 1.05, and may be in the range between about 1.05 and about 1.2. The drive currents of the NFETs in logic device region 100L and SRAM device region 100S, as will be formed subsequently, on the other hand, may have the same drive current or different drive currents.

The weakening of the PFET in SRAM device region 100S and/or the strengthening of the PFET in logic device region 100L may be achieved by meeting any one, two, or three of the following three conditions. The three conditions include, and are not limited to, making the germanium atomic percentage Ge_{L} in logic device region 100L to be greater than the germanium atomic percentage Ge_{S} in SRAM device region 100S, making the boron concentration BC_{L} in logic device region 100L to be greater than the boron concentration BCₛ in SRAM device region 100S, and performing channel-push in logic device region 100L but not in SRAM device region 100S.

In accordance with some embodiments when the germanium atomic percentage Ge_{L} in logic device region 100L is to be greater than the germanium atomic percentage Ge_{S} in SRAM device region 100S, ratio Ge_{L}/Ge_{S} may be greater than about 2, and may be in the range between about 2 and about 4.

In accordance with some embodiments when the boron concentration BC_{L} in logic device region 100L is to be greater than the boron concentration BC_{S} in SRAM device region 100S, ratio BC_{L}/BC_{S} may be greater than about 2, and may be in the range between about 2 and about 1,000.

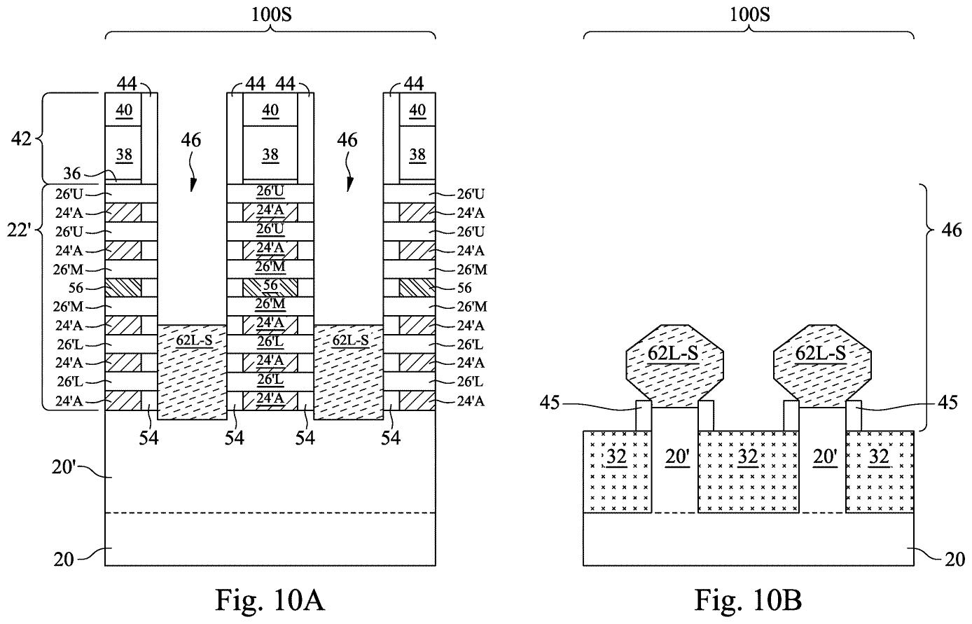

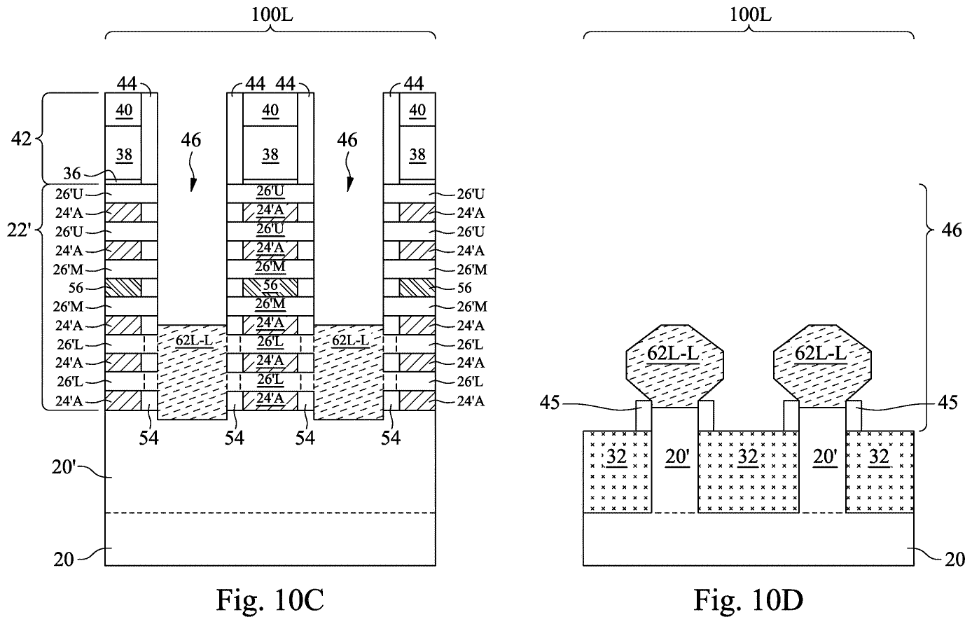

In a subsequent process, the protection liner 49S (FIGS. 9A and 9B) is removed, and the resulting structure is shown in FIGS. 10A, 10B, 10C, and 10D. The respective process is illustrated as process 230 in the process flow 200 as shown in FIG. 15. The removal process may be performed through an isotropic etching process using a wet etching solution or an etching gas that attacks protection liner 49S, but not the materials of other exposed features including protection layers 48S and 48L, lower source/drain regions 62L, inner spacers 54, and semiconductor strip 20'.

Next, protection layers 48S and 48L are removed. The respective process is illustrated as process 232 in the process flow 200 as shown in FIG. 15. The removal may be performed through an isotropic etching process, wherein a wet etching process or a dry etching process may be adopted. The etching chemical is selected as not etching inner spacers 54, lower source/drain regions 62L-S and 62L-L, upper semiconductor nanostructures 26′U, and other exposed materials such as gate spacers 44 and hard masks 40. The resulting structures are shown in FIGS. 10A, 10B, 10C, and 10D.

In accordance with alternative embodiments, the etching chemical for removing the protection liner 49S is the same for removing protection layers 48S and 48L. Accordingly, a same process may be used to remove the protection liner 49S and the protection layers 48S and 48L.

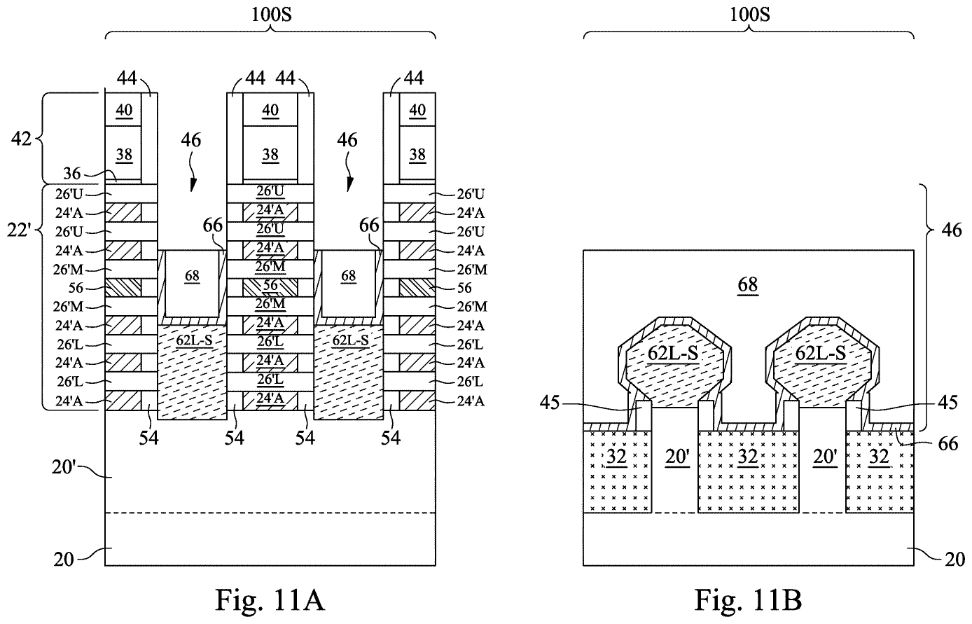

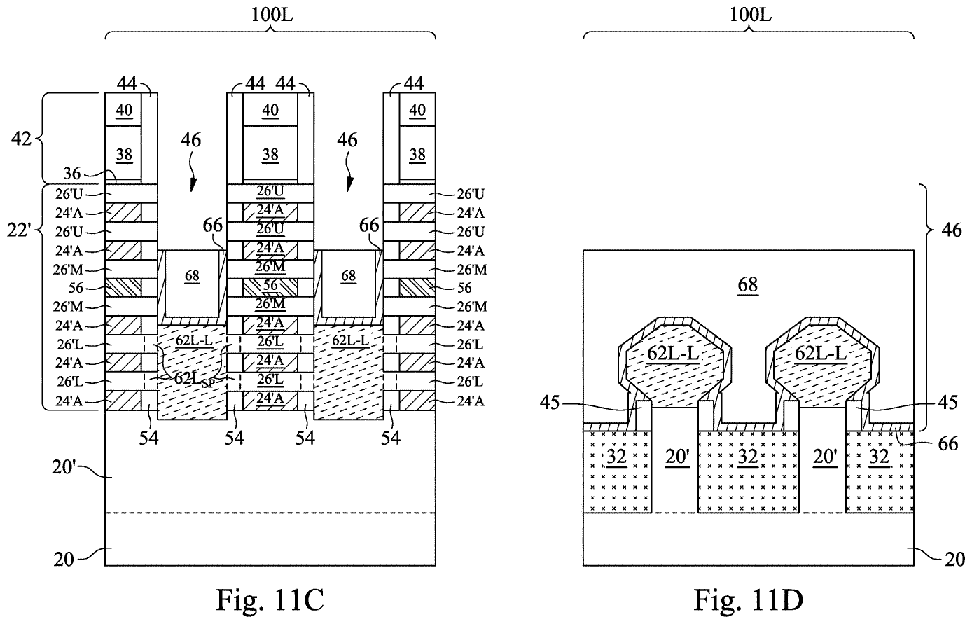

Referring to FIGS. 11A, 11B, 11C, and 11D, a first contact etch stop layer (CESL) 66 and a first ILD 68 are formed. The respective process is illustrated as process 234 in the process flow 200 as shown in FIG. 15. The first CESL 66 and first ILD 68 may be formed simultaneously in SRAM device region 100S and logic device region 100L. The first CESL 66 may be formed of a dielectric material having a high etching selectivity than the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

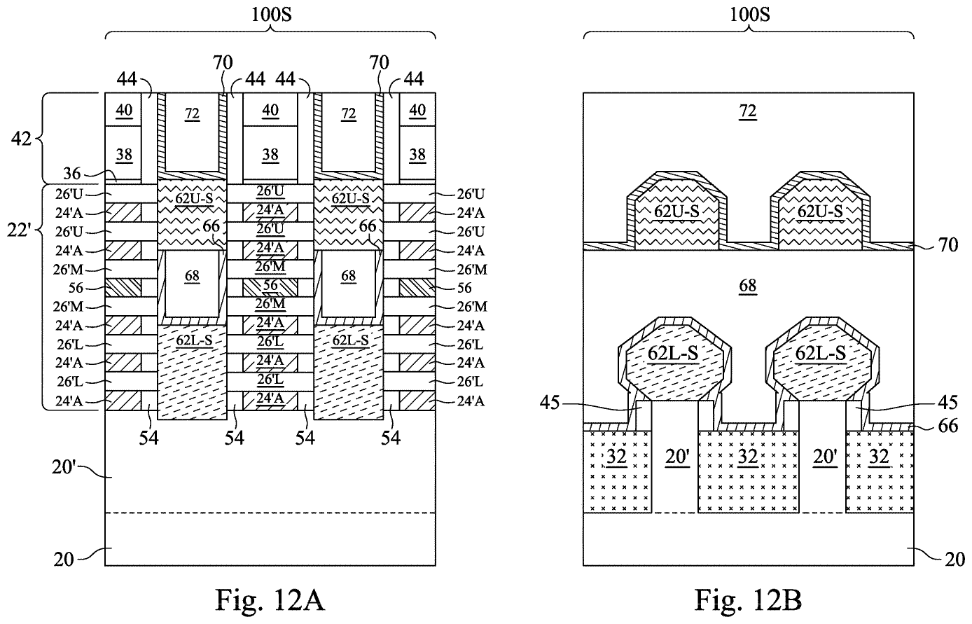

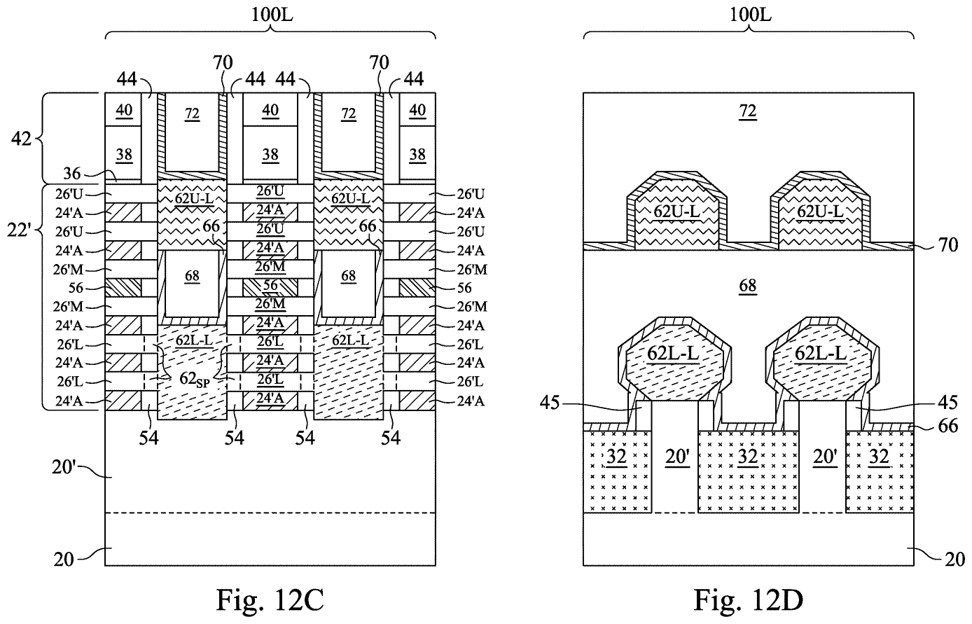

Next, referring to FIGS. 12A, 12B, 12C, and 12D, upper epitaxial source/drain regions 62U-S and 62U-L are formed in the upper portions of the source/drain recesses 46, and may be formed simultaneously (or in separate processes) in SRAM device region 100S and logic device region 100L. The respective process is illustrated as process 236 in the process flow 200 as shown in FIG. 15. Accordingly, the upper epitaxial source/drain regions 62U-S in SRAM device region 100S may have the same structure and same compositions as the upper epitaxial source/drain regions 62U-L in logic device region 100L.

The conductivity type of the upper epitaxial source/drain regions 62U-S and 62U-L may be opposite to the conductivity type of the lower source/drain regions 62L-S and 62L-L. Alternatively stated, the upper epitaxial source/drain regions 62U-S and 62U-L may be oppositely doped than the lower source/drain regions 62L-S and 62L-L. The upper epitaxial source/drain regions 62U-S and 62U-L may be in-situ doped, and/or may be implanted, with an n-type or p-type dopant. For example, when the upper epitaxial source/drain regions 62U-S and 62U-L are n-type semiconductor region, SiP, SiCP, or the like may be adopted.

Next, a second CESL 70 and a second ILD 72 are formed. The second CESL 70 and second ILD 72 may be formed simultaneously in SRAM device region 100S and logic device region 100L. The respective process is illustrated as process 238 in the process flow 200 as shown in FIG. 15. The materials and the formation methods of the second CESL 70 and a second ILD 72 may be similar to the materials and the formation methods of the first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

Next, the dummy gate stacks 42 are removed in one or more etching processes, so that recesses are formed. Each of the recesses exposes and/or overlies portions of multi-layer stacks 22′. The remaining portions of the dummy nanostructures 24′A (FIGS. 12A and 12C) are then removed through etching, so that the recesses extend between the semiconductor nanostructures 26′U.

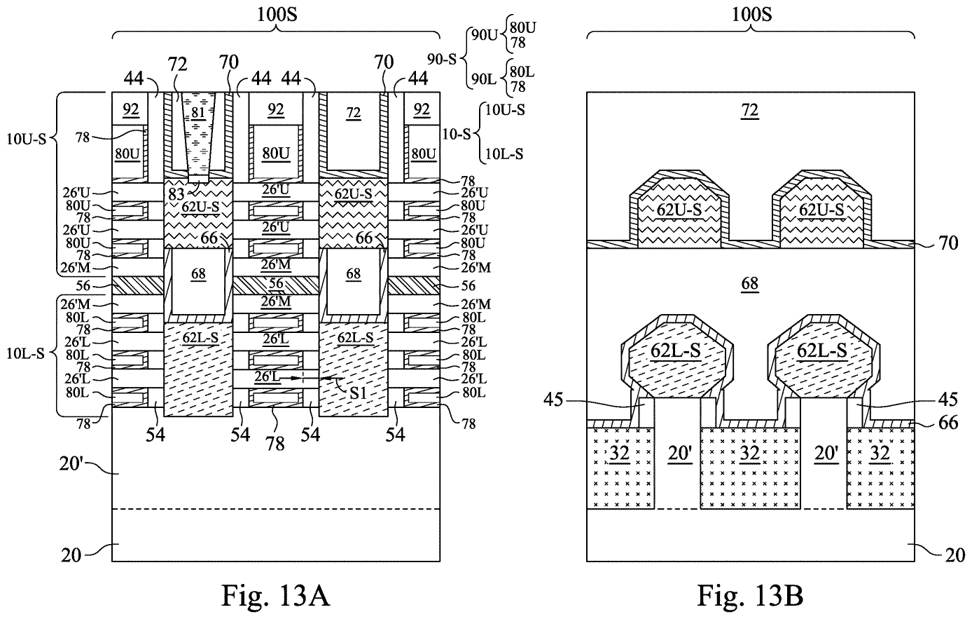

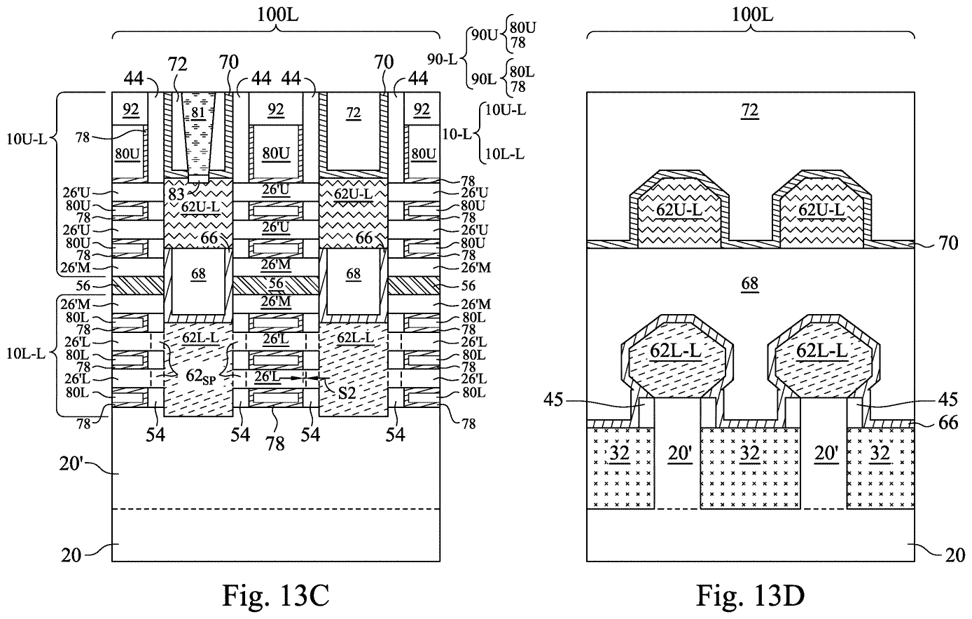

In FIGS. 13A, 13B, 13C, and 13D, gate dielectrics 78 are formed on the exposed semiconductor nanostructures 26′. The gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′.

Replacement gate stacks 90-S and 90-L (each including gate stacks 90L and 90U) are then formed in the respective recesses, and may be formed in the SRAM device region 100S and logic device region 100L simultaneously. The respective process is illustrated as process 240 in the process flow 200 as shown in FIG. 15. Gate stacks 90L include gate spacers 78 and gate electrodes 80L. Gate stacks 90U include gate spacers 78 and gate electrodes 80U. Each of gate dielectrics 78 may include an interfacial layer (such as a silicon oxide layer) and a high-k dielectric layer over the interfacial layer.

Dielectric hard masks 92 are formed over the gate stacks 90U. The gate electrodes 80L and 80U include conductive materials, which may provide suitable work-functions to the resulting lower FETs (lower transistors) 10L-S and 10L-L and upper FETs (upper transistors) 10U-S and 10U-L. The gate electrodes 80L and 80U may be common gates formed in a same formation process.

FIGS. 13A and 13C further illustrate the formation of source/drain contact plugs 81 connecting to upper source/drain regions 62U-S and 62U-L in accordance with some embodiments. Source/drain silicide layers 83 are also formed. The electrical connection to the lower source/drain regions 62L-S and 62L-L may be through vertical interconnects. CFETs 10-S and 10-L are thus formed. SRAM CFET 10-S includes NFET 10U-S and PFET 10L-S. Logic CFET 10-L includes NFET 10U-L and PFET 10L-L.

In accordance with some embodiments, the epitaxy source/drain region 62L-S (such as a SiGe region) may have lateral spacing S1 (FIG. 13A) from the channel region (formed of Si, for example) of the respective lower transistor 10L-S. The epitaxy source/drain region 62L-L (such as a SiGe region) may have lateral spacing S2 (FIG. 13C) from the channel region (formed of Si, for example) of the respective lower transistor 10L-S. Lateral spacing S2 may be equal to lateral spacing S1 if no channel-push is performed, or may be smaller than lateral spacing S1 if channel-push is performed.

In accordance with some embodiments, as shown in preceding figures, the number of upper semiconductor nanostructures 26′U (channels) are the same as the number of lower semiconductor nanostructures 26′L (channels). For example, the illustrated figures show that both of the number of upper semiconductor nanostructures 26′U and the number of lower semiconductor nanostructures 26′L are equal to two. In accordance with alternative embodiments, the number of channels of the NFETs may be smaller than (or greater than) the number of channels of PFETs. For example, assuming the upper FETs are NFETs, and the lower FETs are PFETs, the number of upper semiconductor nanostructures 26′U may also be smaller than (or greater than) the number of lower semiconductor nanostructures 26′L.

FIG. 14 illustrates a circuit diagram of SRAM cell 100 in accordance with some embodiments. SRAM cell 100 includes pull-up transistors PU-1 and PU-2, which are PFETs. SRAM cell 100 further includes pull-down transistors PD-1 and PD-2 and pass-gate transistors PG-1 and PG-2, which are NFETs. The gates of pass-gate transistors PG-1 and PG-2 are controlled by word-line WL that determines whether SRAM cell 100 is selected or not.

A latch formed of pull-up transistors PU-1 and PU-2 and pull-down transistors PD-1 and PD-2 stores a bit, wherein the complementary values of the bit are stored in storage nodes SN-1 and SN-2. The stored bit can be written into or read from SRAM cell 100 through complementary bit lines including bit-line (BL) and bit-line bar (BLB).

In accordance with some embodiments, pull-up transistors PU-1 and pull-down transistors PD-1 (and/or pull-up transistors PU-2 and pull-down transistors PD-2) may be formed through the aforementioned processes, and are implemented through PFET 10L-S and NFET 10U-S, respectively, as shown in FIG. 13A. PFET 10L-L and NFET 10U-L (FIG. 13C), on the other hand, may be used to formed logic circuits, such as the inverters of the logic circuits.

The embodiments of the present disclosure have some advantageous features. By adopting the processes of the present disclosure, the PFETs of some circuits such as SRAM circuits may be weakened in accordance with the embodiments of the present application. This process is compatible with the monolithic formation process of CFETs. The CFETs of the logic devices, on the other hand, may not be weakened, or may be strengthened.

In accordance with some embodiments of the present disclosure, a method comprises forming a first multilayer stack in a first device region; forming a first dummy gate stack over the first multilayer stack; forming a second multilayer stack in a second device region; forming a second dummy gate stack over the second multilayer stack; etching the first multilayer stack to form a first source/drain recess; etching the second multilayer stack to form a second source/drain recess; in a first epitaxy process, forming a first lower source/drain region in the first source/drain recess, wherein the first lower source/drain region is of a first conductivity type; in a second epitaxy process separate from the first epitaxy process, forming a second lower source/drain region in the second source/drain recess, wherein the second lower source/drain region is of the first conductivity type.

In an embodiment, in a third epitaxy process, the method further comprises forming both of a first upper source/drain region in the first source/drain recess and a second upper source/drain region in the second source/drain recess, respectively, wherein the first upper source/drain region and the second upper source/drain region are of a second conductivity type opposite to the first conductivity type.

In an embodiment, the first conductivity type is p-type, and the second conductivity type is n-type. In an embodiment, the first device region is a static random-access memory device region, and the second device region is a logic device region. In an embodiment, the first lower source/drain region has a lower germanium atomic percentage than the second lower source/drain region. In an embodiment, the first lower source/drain region has a lower p-type dopant concentration than the second lower source/drain region.

In an embodiment, the forming the second lower source/drain region comprises a channel-push process, and the forming the first lower source/drain region is free from the channel-push process. In an embodiment, the method further comprises replacing the first dummy gate stack with a first replacement gate stack, and replacing the second dummy gate stack with a second replacement gate stack. In an embodiment, the first replacement gate stack and the second replacement gate stack are formed sharing common processes.

In accordance with some embodiments of the present disclosure, a method comprises forming a first source/drain recess in a first device region, wherein the first source/drain recess is between first neighboring multilayer stacks; forming a second source/drain recess in a second device region, wherein the second source/drain recess is between second neighboring multilayer stacks, and wherein the first source/drain recess and the second source/drain recess are formed in a common process; forming a first dielectric liner in the second source/drain recess and on surfaces of the second neighboring multilayer stacks; selectively growing a first lower source/drain region in the first source/drain recess; removing the first dielectric liner; forming a second dielectric liner in the first source/drain recess and on surfaces of the first neighboring multilayer stacks; selectively growing a second lower source/drain region in the second source/drain recess, wherein the first lower source/drain region and the second lower source/drain region are of a same first conductivity type; and removing the second dielectric liner.

In an embodiment, the method further comprises forming a first protection layer in a first upper portion of the first source/drain recess, wherein the second dielectric liner is formed on the first protection layer; and forming a second protection layer in a second upper portion of the second source/drain recess, wherein the first dielectric liner is formed to contact the second protection layer. In an embodiment, at a first time after the first dielectric liner is removed, the second protection layer remains, and wherein at a second time after the second dielectric liner is removed, the first protection layer remains. In an embodiment, the same first conductivity type is p-type.

In an embodiment, the method further comprises forming a first upper source/drain region and a second upper source/drain region in the first source/drain recess and the second source/drain recess, respectively, wherein the first upper source/drain region and the second upper source/drain region are formed in a same epitaxy process. In an embodiment, the method further comprises forming a first upper source/drain region and a second upper source/drain region in the first source/drain recess and the second source/drain recess, respectively, wherein the first upper source/drain region and the second upper source/drain region are n-type regions.

In an embodiment, the selectively forming the second lower source/drain region comprises a channel-push process, and wherein the selectively forming the first lower source/drain region is free from channel-push. In an embodiment, the first lower source/drain region and the second lower source/drain region have a difference selected from the group consisting of different germanium atomic percentages, different boron concentrations, and combinations thereof.

In accordance with some embodiments of the present disclosure, a structure comprises a first lower transistor in a first device region, wherein the first lower transistor comprises a first source/drain region of a first conductivity type, and wherein the first lower transistor has a first drive current; a second lower transistor in a second device region, wherein the second lower transistor comprises a second source/drain region of the first conductivity type, wherein the second lower transistor has a second drive current lower than the first drive current; a first upper transistor overlapping the first lower transistor, wherein the first upper transistor comprises a first upper source/drain region of a second conductivity type opposite to the first conductivity type; and a second upper transistor overlapping the second lower transistor, wherein the second upper transistor comprises a second upper source/drain region of the second conductivity type.

In an embodiment, the first upper transistor and the second upper transistor have a same drive current. In an embodiment, the second lower transistor differs from the first lower transistor by a difference selected from the group consisting of the second lower transistor has a lower germanium atomic percentage than the first lower transistor, the second lower transistor has a lower boron concentration than the first lower transistor, and combinations thereof.

In an embodiment, the first lower transistor comprises a first channel region, and the first source/drain region comprises a first silicon germanium region having a first lateral distance from the first channel region; and the second lower transistor comprises a second channel region, and the second source/drain region comprises a second silicon germanium region having a second lateral distance from the second channel region, and wherein the second lateral distance is smaller than the first lateral distance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first p-type transistor in a static random access memory region, the first p-type transistor having a first drive current, and the first p-type transistor is formed by processes comprising:
depositing a first source/drain region comprising silicon, wherein the first source/drain region has a first germanium atomic percentage; and
forming a second p-type transistor in a logic region, the second p-type transistor having a second drive current different from the first drive current, and the second p-type transistor is formed by processes comprising:
depositing a second source/drain region comprising silicon germanium, wherein the second source/drain region has a second germanium atomic percentage higher than the first germanium atomic percentage; and
forming a first inter-layer dielectric over the first source/drain region and the second source/drain region, wherein portions of the first inter-layer dielectric in the static random access memory region and the logic region are formed simultaneously.

2. The method of claim 1 further comprising:
depositing a third source/drain region and a fourth source/drain region overlapping the first source/drain region and the second source/drain region, respectively, wherein the third source/drain region and the fourth source/drain region are n-type source/drain regions.

3. The method of claim 2, wherein the first source/drain region and the second source/drain region are formed through separate epitaxy processes, and wherein the third source/drain region and the fourth source/drain region are deposited in a common epitaxy process.

4. The method of claim 2 further comprising forming a second inter-layer dielectric over the third source/drain region and the fourth source/drain region, wherein portions of the second inter-layer dielectric in the static random access memory region and the logic region are formed simultaneously.

5. The method of claim 1, wherein the first source/drain region has a first p-type dopant concentration, and the second source/drain region has a second p-type dopant concentration higher than the first p-type dopant concentration.

6. The method of claim 1, wherein the processes for forming the second p-type transistor comprise a channel-push process, and wherein the processes for forming the first p-type transistor is free from any channel-push process.

7. The method of claim 6, wherein the channel-push process results in a sidewall of a channel region that is in contact with the second source/drain region to be recessed to a first position vertically aligned to a second position between opposing sidewalls of an overlying inner spacer.

8. The method of claim 1, wherein the first drive current is lower than the second drive current.

9. A method comprising:
forming a first complementary field-effect transistor comprising:
forming a first p-type transistor;
depositing a first portion of an inter-layer dielectric overlapping the first p-type transistor; and
forming a first n-type transistor overlapping the first portion of the inter-layer dielectric; and
forming a second complementary field-effect transistor comprising:
forming a second p-type transistor, wherein the first p-type transistor and the second p-type transistor are formed by separate formation processes;
depositing a second portion of the inter-layer dielectric overlapping the second p-type transistor; and
forming a second n-type transistor overlapping the second portion of the inter-layer dielectric, wherein the first n-type transistor and the second n-type transistor are formed by a same epitaxy process.

10. The method of claim 9, wherein the first p-type transistor has a lower drive current than the second p-type transistor.

11. The method of claim 9, wherein the first p-type transistor and the first n-type transistor are comprised in a static random-access memory cell, and act as a pull-up transistor and a pull-down transistor, respectively.

12. The method of claim 11, wherein the second p-type transistor and the second n-type transistor are comprised in an inverter of a logic circuit.

13. The method of claim 9, wherein the forming the first p-type transistor comprising epitaxially growing a first p-type source/drain region, and wherein the first p-type source/drain region has a lower germanium atomic percentage than a second p-type source/drain region of the second p-type transistor.

14. The method of claim 13, wherein the first p-type source/drain region has a lower p-type dopant concentration than the second p-type source/drain region.

15. The method of claim 9, wherein the forming the second p-type transistor comprises a channel-push process, and wherein the forming the second p-type transistor is free from channel-push.

16. A method comprising:
forming a first p-type transistor;
forming a second p-type transistor, wherein p-type source/drain regions of the first p-type transistor and the second p-type transistor are formed by separate formation processes;
depositing a first inter-layer dielectric over the first p-type transistor and the second p-type transistor;
forming a first n-type transistor overlying or underlying the first p-type transistor;
forming a second n-type transistor overlying or underlying the second p-type transistor, wherein n-type source/drain regions of the first n-type transistor and the second n-type transistor are formed simultaneously; and
depositing a second inter-layer dielectric over the first n-type transistor and the second n-type transistor.

17. The method of claim 16, wherein the first p-type transistor is formed as having a lower drive current than the second p-type transistor.

18. The method of claim 16, wherein the n-type source/drain regions of the first n-type transistor and the second n-type transistor are formed through a same epitaxy process.

19. The method of claim 16, wherein the first p-type transistor and the first n-type transistor are comprised in a static random access memory cell.

20. The method of claim 19, wherein the second p-type transistor and the second n-type transistor are comprised in an inverter.
